(19) United States
(12) Patent Application Publication
(10) Pub. No.: US 2012/0309115 A1
(43) Pub. Date: Dec. 6, 2012

(54) APPARATUS AND METHODS FOR SUPPORTING AND CONTROLLING A SUBSTRATE

(75) Inventors: BLAKE KOELMEL, Mountain View, CA (US); Joseph M. Ranish, San Jose, CA (US)

(73) Assignee: APPLIED MATERIALS, INC., Santa Clara, CA (US)

(21) Appl. No.: 13/152,157

(22) Filed: Jun. 2, 2011

(51) Int. Cl. H01L 21/66; A47B 81/00

(52) U.S. Cl. 438/5; 438/14; 312/237; 312/236; 257/E21.529

(57) ABSTRACT

Embodiments of the present invention provide apparatus and methods for supporting and controlling a substrate during thermal processing. One embodiment of the present invention provides an apparatus for processing a substrate. The apparatus includes a chamber body defining an inner volume, a substrate support disposed in the inner volume, and an auxiliary force assembly configured to apply an auxiliary force to the substrate. Another embodiment provides a gas delivery assembly configured to adjust a thermal mass of a fluid flow delivered to position, control and/or rotate a substrate.

### BACKGROUND OF THE INVENTION

1. Field of the Invention

Embodiments of the present invention generally relate to apparatus and methods for processing a substrate. More particularly, embodiments of the present invention provide apparatus and methods for supporting a substrate during thermal processing.

2. Description of the Related Art

During semiconductor processing, particularly during thermal processing, a substrate being supported by a traditional substrate support may warp, bow, and even break due to the thermal gradient caused by rapid thermal heating. In some cases, the deformation of the substrate may lead to thermal non-uniformity across the substrate because deformation causes different areas of the substrate to have different exposure to the heat sources.

Therefore, there is a need for improved apparatus and methods for supporting and controlling a substrate during thermal processing.

### SUMMARY

Embodiments of the present invention generally provide apparatus and methods for processing a substrate. More particularly, embodiments of the present invention provide apparatus and methods for handling a substrate during thermal processing.

One embodiment of the present invention provides an apparatus for processing a substrate. The apparatus includes a chamber body defining an inner volume, a substrate support disposed in the inner volume, and an auxiliary force assembly configured to apply an auxiliary force to the substrate. The substrate support comprises a substrate support body having an upper surface. A plurality of ports are formed on the upper surface. The ports are configured to deliver a plurality of fluid flows to support, position and/or rotate a substrate over the upper surface. The auxiliary force is configured to adjust a vertical position of the substrate or adjust a profile of the substrate.

Another embodiment of the present invention provides a method for handling a substrate. The method includes delivering a plurality of fluid flows to a plurality of ports formed on an upper surface of a substrate support in a processing chamber, receiving a substrate over the plurality of fluid flows so that the substrate floats over the upper surface of the substrate support, and applying an auxiliary force to the substrate to reduce deformation of the substrate without directly contacting the substrate.

Yet another embodiment of the present invention provides a method for handling a substrate during thermal processing. The method includes delivering a plurality of fluid flows to a plurality of ports formed on an upper surface of a substrate support in a processing chamber, receiving a substrate over the plurality of fluid flows so that the substrate floats over the upper surface of the substrate support, monitoring a temperature profile of the substrate, and adjusting a thermal mass of one or more of the plurality of fluid flows to adjust the temperature profile of the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic sectional side view of a thermal processing chamber according to one embodiment of the present invention.

FIG. 1B is a schematic top view of the thermal processing chamber of FIG. 1A with a lamp assembly removed.

FIGS. 2A-2D schematically illustrate a substrate with improved flatness under a counter force according to embodiments of the present invention.

FIG. 3 schematically illustrates a substrate support having a plurality of ports for supporting a substrate and an electrostatic chuck for applying a counter force according to one embodiment of the present invention.

FIG. 4 is a flow chart of a method for supporting a substrate with an improved thermal uniformity according to one embodiment of the present invention.

FIG. 5 is a flow chart of a method for maintaining flatness of a substrate according to one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to a method and apparatus for processing a substrate. Particularly embodiments of the present invention provide apparatus and methods for supporting a substrate during thermal processing. Embodiments of the present invention provide a processing chamber having improved substrate control during processing by using fluid flows to handle the substrate, using adjustable fluid composition to adjust substrate temperature, and/or using an auxiliary force to counter the fluid flows to maintain flatness of the substrate.

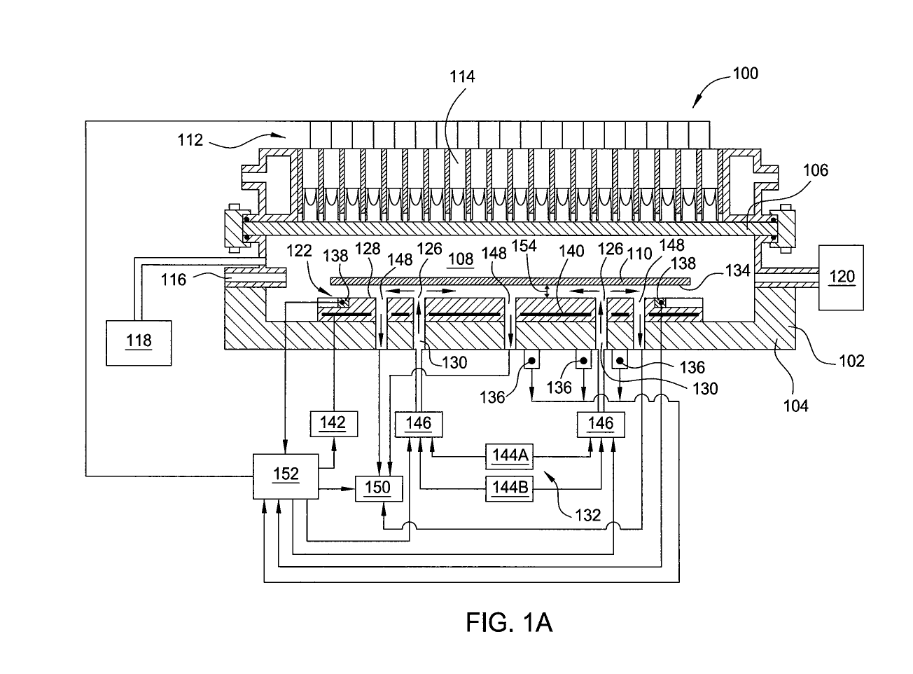

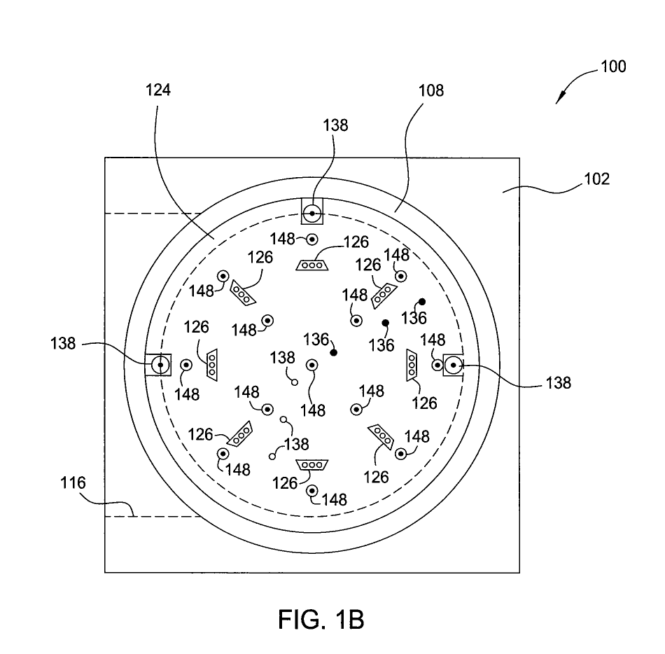

FIG. 1A is a schematic sectional side view of a thermal processing chamber 100 according to one embodiment of the present invention. The thermal processing chamber 100 is configured to perform a rapid thermal processing of a substrate.

The thermal processing chamber 100 includes sidewalls 102, a chamber bottom 104 coupled to the sidewalls 102, and a quartz window 106 disposed over the sidewalls 102. The sidewalls 102, the chamber bottom 104 and the quartz windows 106 define an inner volume 108 for processing a substrate 110 therein. A heating assembly 112 is disposed above the quartz window 106 and configured to direct thermal energy towards the inner volume 108 through the quartz window 106. The heat assembly 112 includes a plurality of heating elements 114. In one embodiment, the plurality of heating elements 114 are a plurality of lamps. The plurality of heating elements 114 may be controlled by a system controller 152. In one embodiment, the plurality of heating elements 114 may be controlled individually or by group.

A slit valve door 116 may be formed through the sidewalls 102 for transferring a substrate therethrough. The thermal processing chamber 100 is coupled to a gas source 118 configured to provide one or more processing gases to the inner volume 108 during processing. A vacuum pump 120 may be coupled to the thermal processing chamber 100 for pumping out the inner volume 108.

FIG. 1B is a schematic top view of the thermal processing chamber 100 of FIG. 1A with the heating assembly 112 removed.

A substrate support 122 is disposed in the inner volume 108 and configured to support, position, and/or rotate the substrate 110 during processing. Particularly, the substrate support 122 is a non-contact substrate supporting device using flows of fluid to support, position and/or rotate the substrate 110.

In one embodiment, the substrate support 122 includes a substrate support body 124 disposed over the chamber bottom 104. A plurality of ports 126 are formed on an upper surface 128 of the substrate support body 124. FIG. 1B illustrates an exemplary arrangement of the plurality of ports 126 according to one embodiment of the present invention.

The plurality of ports 126 are connected to a fluid delivery system 132 through a plurality of channels 130 formed in the substrate support body 124. In one embodiment, the fluid delivery system 132 is configured to deliver one or more gases, such as nitrogen, helium, argon, krypton, neon, hydrogen, or combinations thereof. Alternatively, the fluid delivery system 132 may be configured to deliver flows of liquid, such as water, to the plurality of ports 126.

The plurality of ports 126 are configured to direct a plurality of fluid flows to a substrate region near the upper surface 128 towards a lower surface 134 of the substrate 110 to support and move the substrate 110 using friction generated and momentum transferred when the fluid flows strike the lower surface 134 of the substrate 110. The substrate 110 is supported, positioned, and/or rotated in the substrate region by controlling the characteristics of the fluid flows delivered from the plurality of ports 126, such as the rates and directions of the plurality of fluid flows. The force imparted by each fluid flow can be combined to cause the substrate 110 to be moved and be positioned as needed.

Detailed description of an exemplary substrate positioning assembly using fluid flow may be found in United States Patent Publication No. 2008/0280453, entitled “Apparatus and Method for Supporting, Positioning and Rotating a Substrate in a Processing Chamber”.

The thermal processing chamber 100 may include a plurality of thermal sensors 136 configured to measure temperatures of the substrate 110 at various locations. The plurality of thermal sensors 136 may be disposed in openings formed through the chamber bottom 104. In one embodiment, the plurality of thermal sensors 136 are pyrometers. As shown in FIG. 1B, the plurality of thermal sensors 136 may be disposed at different radial locations to measure temperature of the substrate 110 at different radial locations for generating a temperature profile of the substrate 110 during processing. The plurality of thermal sensors 136 are coupled to the system controller 152. In one embodiment, the system controller 152 may be configured to generate a thermal profile of the substrate 110 using signals received from the plurality of thermal sensors 136.

The thermal processing chamber 100 also includes two or more position sensors 138 configured to detecting the position of the substrate 110 in the thermal processing chamber 100. In one embodiment, the position sensors 138 are capacitive sensors configured to detect the relative location of the perspective portion of the substrate 110. The plurality of position sensors 138 are coupled to the system controller 152. The position sensors 138 may be used together or alone to determine various characteristics of the substrate 110, such as vertical position, horizontal position, levelness, flatness, rotational speed, rotational direction. Detailed description of using capacitive sensors to detect characteristics of a substrate can be found in U.S. patent application Ser. No. ______, entitled “Apparatus and Methods for Positioning a Substrate Using Capacitive Sensors”.

Alternatively, the position sensors 138 may be optical sensors, or other suitable sensors for detecting the location of the substrate 110.

According to one embodiment of the present invention, the substrate support 122 is heated to provide thermal energy to the backside of the substrate 110. In one embodiment, the substrate support 122 includes a heater 140 embedded in the substrate support body 124. In one embodiment, the heater 140 may be a resistive heater. A heater power supply 142 may be coupled to the heater 140. The substrate support body 124 may be heated directly by the heater 140 to provide thermal energy to the substrate 110 by thermal radiation and convection by fluid flows between the substrate 110 and the upper surface 128 of the substrate support body 124. In one embodiment, the heater 140 may be maintained at a temperature between about 450° C. to about 720° C. during processing. The heater power supply 142 may be coupled to and controlled by the system controller 152.

According to embodiments of the present invention, the fluid delivery system 132 is configured to deliver fluid flows with adjustable thermal mass to the plurality of ports 126 to adjust temperatures of the substrate 110.

In one embodiment, the fluid delivery system 132 may deliver fluid flows with adjustable thermal mass by adjusting composition of the fluid flows. The fluid delivery system 132 may include two or more fluid sources 144A, 144B. The fluid delivery system 132 also includes a plurality of fluid controlling devices 146. Each fluid controlling device 146 is connected between one of the plurality of ports 126 and the two or more fluid sources 144A, 144B. Each fluid controlling device 146 is configured to adjust a flow rate delivered to a corresponding port 126.

In one embodiment, each fluid controlling device 146 is also capable of adjusting a ratio of fluid from the fluid sources 144A, 144B to adjust the composition of the fluid flow delivered to the corresponding port 126. The fluid source 144A is configured to provide a fluid having a thermal mass different a fluid provided by the fluid source 144B. By adjusting the composition of the fluid flow provided to each port 126, the fluid delivery system 132 can adjust the thermal mass of the fluid flow delivered to each port 126. In one embodiment, each fluid controlling device 146 may be individually controlled by the system controller 152.

The substrate support 122 further includes an auxiliary force assembly configured to apply an auxiliary force to the substrate region to balance or counter effect the fluid flows from the plurality of ports 126 on the substrate 110 in the substrate region.

In one embodiment, the auxiliary force assembly may be configured to apply a vertically downwards force by vacuum. The auxiliary force assembly may include a plurality of vacuum ports 148 connected to a vacuum source 150. In one embodiment of the present invention, the plurality of vacuum ports 148 are open to the upper surface 128 of the substrate support body 124. The plurality of vacuum ports 148 are connected to the vacuum source 150. The plurality of vacuum ports 148 may be distributed at various locations to balance or counter effect forces from the fluid flows delivered from the plurality of ports 126. In one embodiment, each of the plurality of vacuum ports 148 may be individually controlled by the system controller 152.

During processing, the thermal sensors 136, the position sensors 138, the fluid delivery system 132, the vacuum ports 148, and the system controller 152 form a closed loop control system to control characteristics of the substrate 110 to obtain desired processing result.

As discussed above, the substrate support 122 is configured to support, position, and/or rotate the substrate 110 with fluid flows from the plurality of ports 126 while the substrate support body 124 may be heated. The substrate 110 floats above the substrate support 122 without any solid contact with the substrate support body 124.

Heat flux between the substrate 110 and the substrate support body 124 can be controlled by varying fluid flows through the plurality of ports 126 and/or adjusting a distance 154 between the substrate and the upper surface 128 of the substrate support body 124.

Varying the fluid flows may include adjusting flow rates from the plurality of ports 126, and/or adjusting composition of the fluid flows from the plurality of ports 126.

When other conditions, such as the temperature of the heater 140, the composition of the fluid flow, and the distance 154, remain the same, the temperature of the substrate 110 decreases as the flow rates increase. Therefore, increasing the flow rates from the plurality of ports 126 may result in a temperature drop in the substrate 110 and decreasing the flow rates from the plurality of ports 126 may result in a temperature increase in the substrate 110.

As discussed above, the fluid source 144A is configured to provide a fluid having a thermal mass different a fluid provided by the fluid source 144B. In one embodiment, the fluid source 144A is a helium source and the fluid source 144B is a nitrogen source. Nitrogen gas generally has a higher thermal mass from helium gas. When other conditions, such as the temperature of the heater 140, flow rates from the plurality of ports 126, and the distance 154, remain the same, the substrate 110 has a higher temperature when helium gas is used to support the substrate 110 than when nitrogen gas at the same flow rate is used to support the substrate 110.

For example, when the heater 140 is maintained at a temperature of about 720° C. and the inner volume 108 is maintained at atmospheric press, flow rates between about 500 sccm and 2500 sccm is used to support the substrate 110, the temperature of the substrate 110 is about 60° C. higher when helium gas is used than when nitrogen gas at the same flow rate is used. Thus, the temperature of the substrate 110 may vary within a range of about 60° C. when a mixture of nitrogen and helium is used to support the substrate 110. When other processing conditions remain the same, increasing the ratio of nitrogen in a nitrogen/helium mixture used to support the substrate 110 can reduce the temperature of the substrate 110, and reducing the ratio of nitrogen can increase the temperature of the substrate 110.

Therefore, increasing the ratio of the fluid with higher thermal mass from the plurality of ports 126 may result in a temperature drop in the substrate 110 and decreasing the ratio of the fluid with higher thermal mass from the plurality of ports 126 may result in a temperature increase in the substrate 110.

Increasing the distance 154 brings the substrate 110 closer to the heating assembly 112 and away from the substrate support body 124. Thus adjusting the distance 154 may change the temperature of the substrate 110. The distance 154 may be controlled by varying fluid flows from the plurality of the ports 126 or by applying an auxiliary force to counter balance the lifting force from the plurality of the ports 126. Increasing the flow rates from the ports 126 configured to raise the substrate 110 vertically may increase the distance 154, and decreasing the flow rates from the ports 126 configured to raise the substrate 110 vertically may decrease the distance 154.

The auxiliary force maybe applied and/or adjusted to adjust the distance 154. The auxiliary force may be applied to change the distance 154 when it is beneficial to leave the flow rates unchanged. In one embodiment, the auxiliary force may be preloaded with the fluid flows from the plurality of ports 126 and reduced or increased during processing to change the distance 154. In one embodiment, the auxiliary force may be applied by a vacuum load through the plurality of vacuum ports 148.

In one embodiment, the auxiliary force, such as the vacuum force from the vacuum ports 148, is preloaded or constantly applied, to maintain the flatness of the substrate during processing. Maintaining the flatness of the substrate 110 while the substrate 110 is floating allows the substrate 110 free to expand in the radial directions during thermal processing despite thermal gradients within the substrate 110 caused by the heating of the heating assembly 112, the heater 140, or other heating. As a result, bowing, warping, and/or breakage of the substrate 110 during rapid thermal processing is reduced. Additionally, maintaining the flatness of the substrate 110 also ensures temperature uniformity within the substrate 110 because different regions of a flat substrate are positioned at the same distance away to the heating sources.

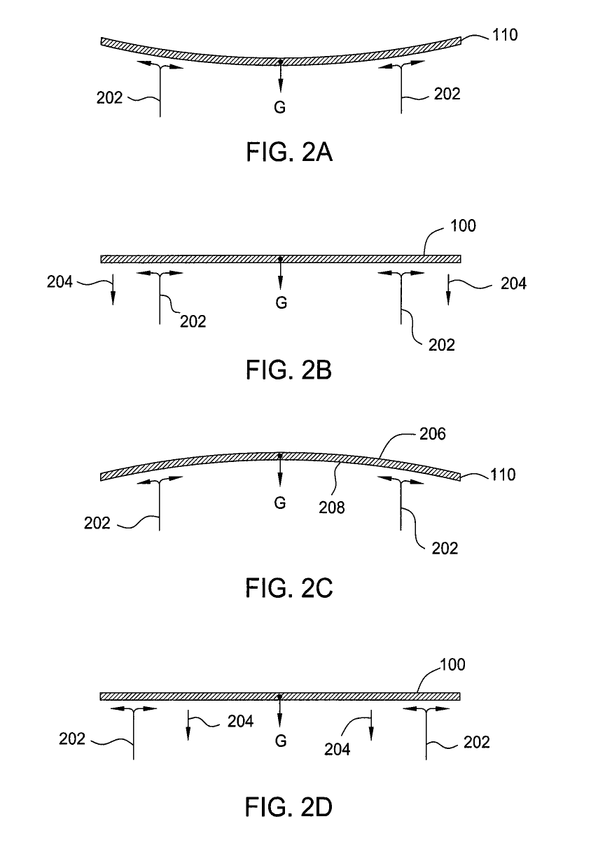

FIGS. 2A-2D schematically illustrate a substrate with improved flatness under a counter force according to embodiments of the present invention.

FIG. 2A schematically illustrates that the substrate 110 bows downwardly near the center under the force of gravity G and supporting fluid flows 202 applied to an outer region of the substrate 110. In FIG. 2B, auxiliary forces 204 are applied to the substrate 110 at locations radially outwards of the fluid flows 202. As a result of the combination of the auxiliary force 204, the lifting force from the fluid flow 202, and the gravity G, the substrate 110 flattens.

FIG. 2C schematically illustrates that the substrate 110 bows upwardly because of the thermal gradient resulted when an upper side 206 of the substrate 110 is heated to a temperature higher than a lower side 208 of the substrate. In FIG. 2D, auxiliary forces 204 are applied to the substrate 110 at locations radially inwards of the fluid flows 202. As a result of the combination of the auxiliary force 204, the lifting force from the fluid flow 202, and the gravity G, the substrate 110 flattens.

The auxiliary force assembly may be configured to apply a force to the substrate 110 by any suitable non-contact means, such as by vacuum force, electrostatic force, electromagnetic force.

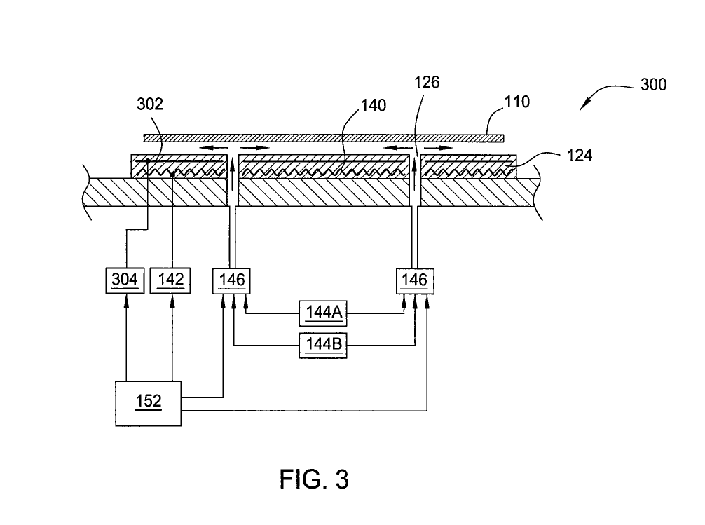

FIG. 3 schematically illustrates a substrate support 300 having a plurality of ports 126 for supporting the substrate 110 with fluid flows and applying an auxiliary force by electrostatic force according to one embodiment of the present invention. The substrate support 300 is similar to the substrate support 122 except the substrate support 300 includes an electrode 302 embedded in the substrate support body 124 and without the vacuum ports 148. The electrode 302 is connected to a power source 304. The power source 304 may be connected to the system controller 152 so that the system controller 152 can control the amount of electrostatic force applied to the substrate 110 from the electrode 302 while the substrate 110 is floating over the substrate support body 124.

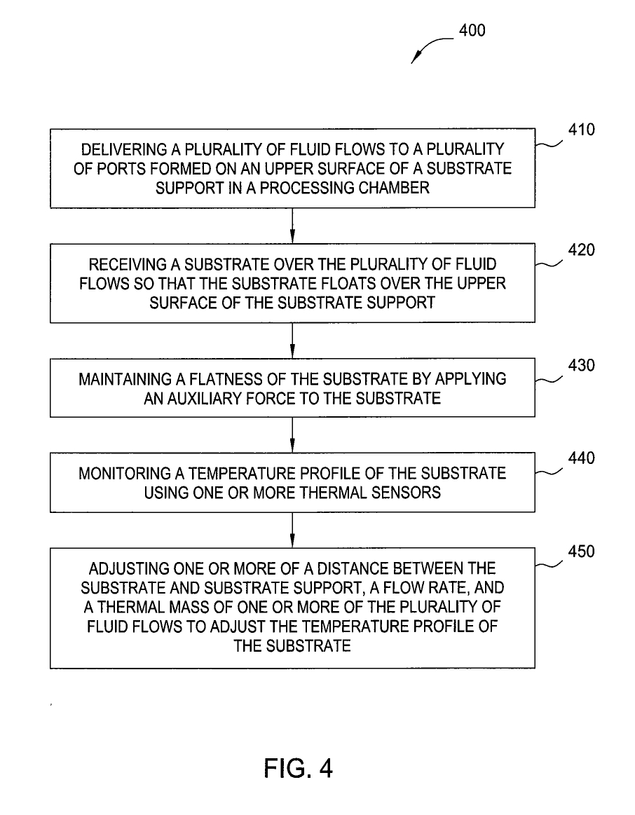

FIG. 4 is a flow chart of a method 400 for supporting a substrate with an improved thermal uniformity according to one embodiment of the present invention. The method 400 may be performed in a processing chamber similar to the processing chamber 100 described above.

In box 410, a plurality of fluid flows are delivered to a plurality of ports formed on an upper surface of a substrate support in a processing chamber. In one embodiment, the substrate support may be heated.

In box 420, a substrate to be processed is received by the plurality of fluid flows and the plurality of fluid flows support the substrate over the upper surface of the substrate support so that the substrate floats. The substrate does not contact the upper surface of the substrate. In one embodiment, the fluid flows from the plurality of ports may also rotate the substrate over the substrate support.

In one embodiment, a thermal processing may be performed when the substrate floats over the substrate support. The substrate may be heated by a heater in the substrate support and/or a heat source disposed above the substrate. In one embodiment, the thermal processing may be a rapid thermal processing wherein the substrate is heated at a high ramp rate.

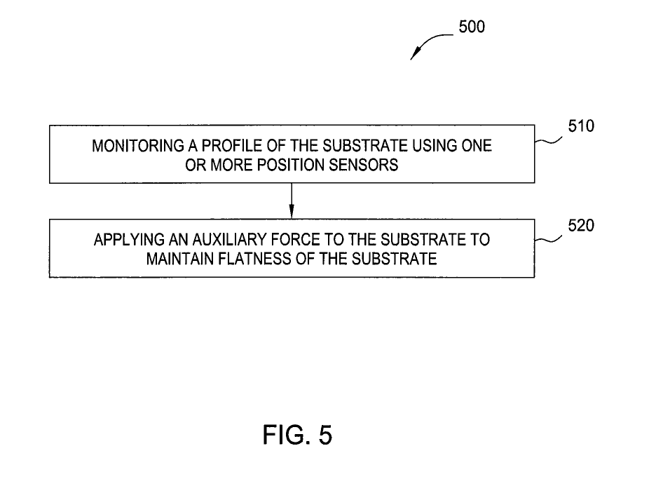

In box 430, the flatness of the substrate may be maintained by applying an auxiliary force to the substrate. Maintaining the flatness of the substrate may be optional. As illustrated in FIGS. 2A-2D, the auxiliary force may be applied to overcome the deformation caused by gravity, fluid flows, or thermal gradient. In one embodiment, the auxiliary force may be preloaded before the substrate is received and adjusted during processing. FIG. 5 describes a method for maintaining a flatness of the substrate in detail.

In box 440, a temperature profile of the substrate may be generated using one or more thermal sensors.

In box 450, one or more processing parameters may be adjusted according to the temperature profile of the substrate obtained in box 440 to adjust a desired temperature profile, such as a uniform temperature profile across the substrate. The processing parameter being adjusted may include one of a distance between the substrate and substrate support, a flow rate of the fluid flows for supporting the substrate, a thermal mass of one or more of the fluid flows, or combinations thereof. In one embodiment, adjusting the distance between the substrate and substrate support may include adding or adjusting an auxiliary force. In one embodiment, the thermal mass of the fluid flow may be adjusted by adjusting a ratio of two fluids having different thermal mass in the fluid flow.

In one embodiment, box 440 and box 450 may be performed repeatedly to during processing.

FIG. 5 is a flow chart of a method 500 for maintaining flatness of a substrate while supporting the by fluid flows according to one embodiment of the present invention. The method 500 may be used in the box 430 of method 400.

In box 510, a profile of a substrate supported by fluid flows while being processed may be monitored using one or more position sensors. In one embodiment, the position sensors may be capacitive sensors directed towards the substrate.

In box 520, an auxiliary force applied to the substrate may be added or adjusted to maintain the flatness of the substrate. In one embodiment, the auxiliary force may be a vacuum force applied through a plurality of vacuum ports formed on an upper surface of the substrate support. In another embodiment, the auxiliary force may be an electrostatic force.

In one embodiment, box 510 and box 520 may be performed repeatedly to maintain the flatness of the substrate during the course of the processing.

Embodiments of the present invention have several advantages over traditional substrate supports for thermal processing. For example, embodiments of the present invention provide non-contact substrate support with control of substrate temperature ramp rates and improve process uniformity by adjusting parameters of the fluid flows, such as composition and/or flow rate of the fluid flows. Embodiments of the present invention also mitigate substrate bowing, warping, and breakage during thermal processing by applying and/or adjusting an auxiliary force to the substrate during processing.

Even though embodiments of the present invention are described with RTP chambers, embodiments of the present invention may be used in any suitable chambers wherein thermal uniformity is needed. For example, embodiments of the present invention may be used in a chemical vapor deposition chamber, an atomic layer deposition chamber, a thermal processing chamber with flash lamps, a laser anneal chamber, a physical vapor deposition chamber, an ion implantation chamber, a plasma oxidation chamber, or a load lock chamber.

While the foregoing is directed to embodiments of the present invention, other and further embodiments of the invention may be devised without departing from the basic scope thereof, and the scope thereof is determined by the claims that follow.

1. An apparatus for processing a substrate, comprising:
a chamber body defining an inner volume;
a substrate support disposed in the inner volume, wherein the substrate support comprises a substrate support body having an upper surface and a plurality of ports formed on the upper surface to deliver a plurality of fluid flows to a substrate region near the upper surface; and
an auxiliary force assembly to deliver an auxiliary force in the substrate region.

2. The apparatus of claim 1, wherein the auxiliary force assembly comprises a vacuum source connected to a plurality of vacuum ports formed on the upper surface of the substrate support body.

3. The apparatus of claim 2, further comprising two or more substrate position sensors.

4. The apparatus of claim 2, further comprising a heater embedded in the substrate support body.

5. The apparatus of claim 4, further comprising:
a first fluid source coupled to the plurality of ports; and
a second fluid source coupled to the plurality of ports, wherein the first and second fluid sources provide fluids having different thermal masses.

6. The apparatus of claim 5, further comprising a plurality of fluid controlling devices coupled between the plurality of ports and the first and second fluid sources, wherein each of the plurality of fluid controlling devices adjusts a ratio of the fluids from the first and second fluid sources.

7. The apparatus of claim 4, further comprising a plurality of thermal sensors disposed in the inner volume.

8. The apparatus of claim 7, further comprising a heating assembly disposed above the inner volume and configured to direct thermal energy towards the substrate region over the substrate support.

9. A method for handling a substrate, comprising:
delivering a plurality of fluid flows to a plurality of ports formed on an upper surface of a substrate support in a processing chamber;
receiving a substrate over the plurality of fluid flows so that the substrate floats over the upper surface of the substrate support; and
applying an auxiliary force to the substrate to maintain flatness of the substrate without directly contacting the substrate.

10. The method of claim 9, further comprising monitoring a profile of the substrate using one or more sensors.

11. The method of claim 10, wherein applying the auxiliary force comprises applying a vacuum force to the substrate through one or more vacuum ports formed on the upper surface of the substrate support.

12. The method of claim 10, wherein applying the auxiliary force comprises applying an electrostatic force to the substrate.

13. The method of claim 10, further comprising heating the substrate support using a heater embedded in the substrate support.

14. The method of claim 9, further comprising adjusting the auxiliary force to adjust a distance between the substrate and the upper surface of the substrate.

15. A method for controlling a substrate during thermal processing, comprising:
delivering a plurality of fluid flows to a plurality of ports formed on an upper surface of a substrate support in a processing chamber;
receiving a substrate over the plurality of fluid flows so that the substrate floats over the upper surface of the substrate support;
monitoring a temperature profile of the substrate; and
adjusting a thermal mass of one or more of the plurality of fluid flows to adjust the temperature profile of the substrate.

16. The method of claim 15, wherein adjusting the thermal mass of one or more of the plurality of fluid flows comprises adjusting a composition of the one or more of the fluid flows.

17. The method of claim 16, wherein each fluid flow comprises a first fluid and a second fluid, the first fluid has a thermal mass higher than a thermal mass of the second fluid, and adjusting the composition of the fluid flow comprises adjusting a ratio of the first fluid and the second fluid.

18. The method of claim 17, wherein the first fluid is helium and the second fluid is nitrogen.

19. The method of claim 16, further comprising applying an auxiliary force to the substrate to maintain flatness of the substrate without directly contacting the substrate.

20. The method of claim 19, wherein applying the auxiliary force comprises applying a vacuum force to the substrate through one or more vacuum ports formed on the upper surface of the substrate support.
